(19) United States
(12) Patent Application Publication
(10) Pub. No.: US 2008/0194077 A1
(43) Pub. Date: Aug. 14, 2008

(54) Method of low temperature wafer bonding through Au/Ag diffusion

(75) Inventors: Cheng-Yi Liu, Jhongli City (TW); Chia-Lun Chang, Kaohsiung City (TW)

Correspondence Address: TROXELL LAW OFFICE PLLC, SUITE 1404, 5205 LEESBURG PIKE, FALLS CHURCH, VA, 22041, US

(73) Assignee: National Central University, Taoyuan County (TW)

(21) Appl. No.: 11/808,127

(22) Filed: Jun. 6, 2007

(30) Foreign Application Priority Data
Feb. 8, 2007 (TW) 096104675
Mar. 28, 2007 (TW) 096110891

(51) Int. Cl. H01L 21/30

(52) U.S. Cl. 438/455; 257/E21.211

(57) ABSTRACT

Two wafers are bonded. One wafer has a gold (Au) film on its surface; the other, a silver (Ag) film. The wafers are stuck together for a bonding process between the Au and the Ag films. Thus, an Au/Ag bonding layer is formed. The bonding layer has a high melting point and so is suitable for high-temperature processes. The bonding process also do no harm to devices on the bonded wafer.

### FIELD OF THE INVENTION

The present invention relates to a wafer bonding; more particularly, relates to obtaining a low temperature wafer bonding through a rapid diffusion between a gold (Au)/silver (Ag) interface to avoid a heat stress out of different coefficients of thermal expansions (CTE).

### DESCRIPTION OF THE RELATED ART

Wafer bonding is a process quite often necessary in many procedures for fabricating electronic devices. And requirements for the wafer bonding include a low stress, a low temperature for the bonding process, and a high-temperature tolerance for following processes.

Traditionally, a conductive film is coated on a substrate through sputtering, where the conductive film is usually made of Au or tin (Sn). However, in fabricating a highly-integrated electronic device, an increased current density may cause a heat stress increased and a temperature heightened. In addition, the different coefficients of thermal expansions (CTE) in the Au/Sn wafer bonding interface would make the interface thin owing to a stress migration. And what is more serious is that the wafer might be broken.

In a word, the prior art does not meet the requirements of a low stress and a tolerance for high-temperature processes, where the wafer may be broken and devices on the wafer may be thus damaged. Hence, the prior art does not fulfill all users' requests on actual use.

### SUMMARY OF THE INVENTION

The main purpose of the present invention is to bond wafers under aq low temperature for obtaining a bonding layer having a melting point above 900° C.

The second purpose of the present invention is to avoid heat stress on bonding multiple wafers.

The third purpose of the present invention is to prevent damages to devices on wafer owing to high-temperature processes.

To achieve the above purposes, the present invention is a method of a low temperature wafer bonding through Au/Ag diffusion, comprising steps of: (a) obtaining a first wafer; (b) coating a chromium (Cr) film, a platinum (Pt) film and a gold (Au) film on the first wafer and cleansing the first wafer; (c) obtaining a second wafer; (d coating a Cr film, a Pt film and a silver (Ag) film on the second wafer and cleansing the second wafer; and (e) sticking the first and the second wafers together and putting the first and the second wafers into a furnace to be bonded through an Au/Ag diffusion under a low temperature to obtain an Au/Ag bonding layer having a melting point above 900° C. Accordingly, a novel method of a low temperature wafer bonding through Au/Ag diffusion is obtained.

### BRIEF DESCRIPTIONS OF THE DRAWINGS

The present invention will be better understood from the following detailed description of the preferred embodiment according to the present invention, taken in conjunction with the accompanying drawings, in which

FIG. 1 is the flow view showing the preferred embodiment according to the present invention;

FIG. 2 is the structural view showing the first wafer;

FIG. 3 is the structural view showing the first wafer coated with a Cr film, a Pt film and an Au film;

FIG. 4 is the structural view showing the second wafer;

FIG. 5 is the structural view showing the second wafer coated with a Cr film, a Pt film and an Ag film; and

FIG. 6 is the structural view showing the preferred embodiment.

### DESCRIPTION OF THE PREFERRED EMBODIMENT

The following description of the preferred embodiment is provided to understand the features and the structures of the present invention.

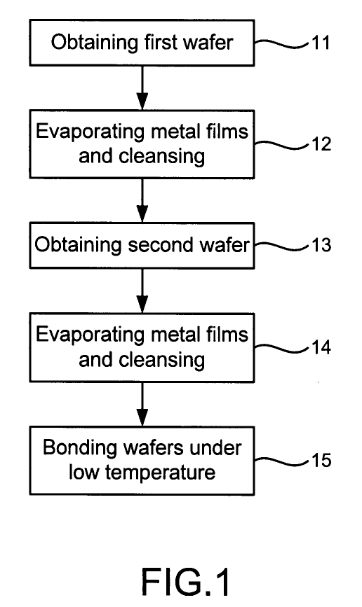

Please refer to FIG. 1 to FIG. 6, which are a flow view showing a preferred embodiment according to the present invention; structural views showing a first wafer and the first wafer coated with a Cr film, a Pt film and an Au film; structural views showing a second wafer and the second wafer coated with a Cr film, a Pt film and an Ag film; and a structural view showing the preferred embodiment. As shown in the figures, the present invention is a method of a low temperature wafer bonding through Au/Ag diffusion, comprising the following step:

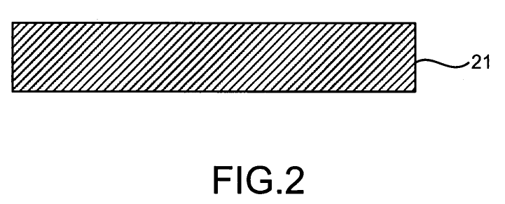

(a) Obtaining a first wafer [11]: As shown in FIG. 2, a first wafer [21] is obtained, where the first wafer [21] is a silicon (Si) wafer.

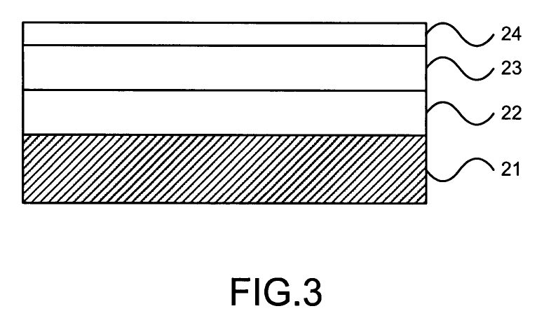

(b) Evaporating metal films and processing a cleansing [12]: As shown In FIG. 3, an electron-gun (E-gun) evaporator with a current between 50 and 250 milli-ampere (mA) is used to sequentially coat a chromium (Cr) film [22], a platinum (Pt) film [23] and a gold (Au) film [24] on the first wafer [21]. Then the first wafer [21] with the coated films are put into a solution having acetone and isopropanol to be cleansed with an ultra-sonic shaker; and then is washed with a de-ionized water and hot-dried with nitrogen (N₂).

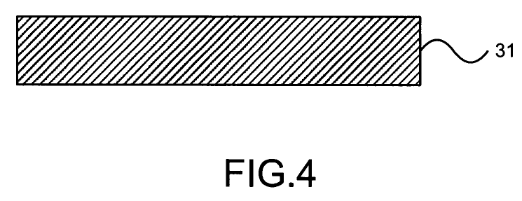

(c) Obtaining a second wafer [13]: As shown in FIG. 4, a second wafer [31] is obtained, where the second wafer [31] is a Si wafer.

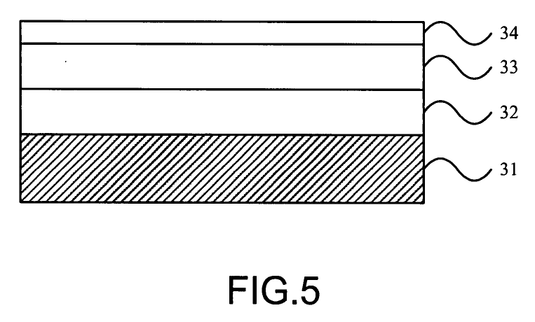

(d) Evaporating metal films and processing a cleansing [14]: As shown in FIG. 5, the E-gun evaporator with a current between 50 and 250 mA is used to sequentially coat a Cr film [32], a Pt film [33] and a silver (Ag) film [34] on the second wafer [31]. Then the second wafer [31] having the coated films are put into the solution having acetone and isopropanol to be cleansed with the ultra-sonic shaker; and then is washed with the de-ionized water and hot-dried with nitrogen (N₂).

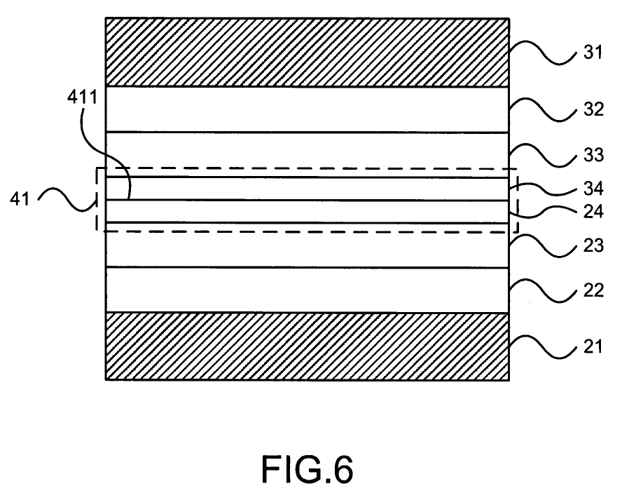

(e) Bonding the wafers under a low temperature [15]: As shown in FIG. 6, the first wafer [21] having the Au film [24] and the second wafer [31] having the Ag film [34] are then stuck together and are put into a furnace to bond the Au film [24] of the first wafer [21] and the Ag film [34] of the second wafer [31] for obtaining an Au/Ag bonding layer [41] through a diffusion between the Au film and the Ag film under a pressure between 10⁻² and 10⁻⁶ torr and a temperature between 100 and 300 Celsius degrees (° C.), where the Au/Ag bonding layer [41] has a melting point above 900° C.

Thus, a novel method of a low temperature wafer bonding through Au/Ag diffusion is obtained.

Consequently, a low temperature wafer bonding is achieved through a rapid diffusion between an Au/Ag interface 411, where a low stress, a low temperature for a bonding process and a high-temperature tolerance for following processes are obtained. Besides, a heat stress is avoid, where the heat stress may be originally obtained owing to different coefficients of thermal expansion (CTE) for different materials on bonding different wafers. Furthermore, the non-porous wafer bonding interface obtained is good for the high-temperature processes that follows; and causes no damage to devices on the bonded wafer.

To sum up, the present invention is a method of a low temperature wafer bonding through Au/Ag diffusion, where a temperature for wafer bonding is reduced owing to a rapid diffusion between an Au/Ag interface; a low stress, a low temperature for a bond in g process and a high-temperature tolerance for following processes is obtained; and a heat stress is avoid, which may be originally obtained owing to different CTE coefficients for different materials on bonding different wafers.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A method of a low temperature wafer bonding through Au/Ag diffusion, comprising steps of:
(a) obtaining a first wafer;
(b) evaporating metal films having a most exterior film of gold (Au) on said first wafer and processing a cleansing;
(c) obtaining a second wafer;
(d) evaporating metal films having a most exterior film of silver (Ag) on said second wafer and processing a cleansing; and
(e) connecting said first wafer and said second wafer and putting said first wafer and said second wafer into a furnace to be bonded under a temperature to obtain an Au/Ag bonding layer through an Au/Ag diffusion.

2. The method according to claim 1, wherein each film of said metal films is variously selected from a group consisting of a chromium (Cr) film, a platinum (Pt) film, an Au film and an Ag film.

3. The method according to claim 1, wherein said cleansing is processed with an ultra-sonic shaker.

4. The method according to claim 1, wherein said temperature in step (e) is located between 100 and 300 Celsius degrees.

5. The method according to claim 1, wherein said bonding is processed for a period between 30 minutes and 4 hours.

6. The method according to claim 1, wherein said furnace has a pressure between 10⁻² and 10⁻⁶ torr.

7. The method according to claim 1, wherein said first wafer and said second wafer are silicon wafers.
